(19) United States
(12) Patent Application Publication
(10) Pub. No.: US 2009/0206832 A1
(43) Pub. Date: Aug. 20, 2009

(54) MAGNETIC SENSOR DEVICE

(76) Inventors: Josephus Arnoldus Henricus Maria Kahlman, Tilburg (NL); Menno Willem Jose Prins, Rosmalen (NL); Jeroen Hans Nieuwenhuis, Waalre (NL)

Correspondence Address: PHILIPS INTELLECTUAL PROPERTY & STANDARDS, P.O. BOX 3001, BRIARCLIFF MANOR, NY, 10510, US

(21) Appl. No.: 12/307,790

(22) PCT Filed: Jul. 2, 2007
(86) PCT No.: PCT/IB07/52558

§ 371 Date: Jan. 7, 2009

(30) Foreign Application Priority Data
Jul. 11, 2006 (EP) 06116957.9

(51) Int. Cl. G01N 27/72; G01R 33/09

(52) U.S. Cl. 324/252

(57) ABSTRACT

The present invention provides a magnetic sensor device comprising means (11, 14) for increasing a binding possibility of magnetic or magnetizable objects (15) e.g. magnetic particles, onto the binding sites by applying a moving magnetic field. The present invention furthermore provides a biochip (40) comprising at least one such magnetic sensor and a method for detecting and/or quantifying target moieties in a sample fluid by using such a magnetic sensor.

The present invention relates to magnetic sensor devices and methods of manufacture and operating the same. More particularly, the present invention relates to a magnetic sensor device, a biochip comprising at least one such magnetic sensor device and to a method for detecting and/or quantifying target moieties in a sample fluid. The magnetic sensor device, biochip and method according to the present invention may be used in molecular diagnostics, biological sample analysis or chemical sample analysis.

Magnetoresistive sensors based on AMR (anisotropic magneto resistance), GMR (giant magneto resistance) and TMR (tunnel magneto resistance) elements are nowadays gaining importance. Besides the known high-speed applications such as magnetic hard disk heads and MRAM, new relatively low bandwidth applications appear in the field of molecular diagnostics (MDx), current sensing in IC's, automotive, etc.

The introduction of micro-arrays or biochips comprising such magnetoresistive sensors is revolutionising the analysis of DNA (desoxyribonucleic acid), RNA (ribonucleic acid) and proteins. Applications are e.g. human genotyping (e.g. in hospitals or by individual doctors or nurses), bacteriological screening, biological and pharmacological research. Such magnetoresistive biochips have promising properties for, for example, biomolecular diagnostics, in terms of sensitivity, specificity, integration, ease of use and costs.

Biochips, also called biosensor chips, biological microchips, gene-chips or DNA chips, consist in their simplest form of a substrate on which a large number of different probe molecules are attached, on well defined regions on the chip, to which molecules or molecule fragments that are to be analysed can bind if they are perfectly matched. For example, a fragment of a DNA molecule binds to one unique complementary DNA (c-DNA) molecular fragment. The occurrence of a binding reaction can be detected, for example by using markers, e.g. fluorescent markers or magnetic labels, that are coupled to the molecules to be analysed. This provides the ability to analyse small amounts of a large number of different molecules or molecular fragments in parallel, in a short time.

In a biosensor an assay takes place. Assays generally involve several fluid actuation steps, i.e. steps in which materials are brought into movement. Examples of such steps are mixing (e.g. for dilution, or for the dissolution of labels or other reagents into the sample fluid, or labelling, or affinity binding) or the refresh of fluid near to a reaction surface in order to avoid that diffusion becomes rate-limiting for the reaction. Preferably the actuation method should be effective, reliable and cheap.

One biochip can hold assays for 1000 or more different molecular fragments. It is expected that the usefulness of information that can become available from the use of biochips will increase rapidly during the coming decade, as a result of projects such as the Human Genome Project, and follow-up studies on the functions of genes and proteins.

A biosensor consisting of an array of, for example 100, sensors based on the detection of e.g. superparamagnetic beads may be used to simultaneously measure the concentration of a large number of different biological molecules (e.g. protein, DNA) in a solution (e.g. blood). This may be achieved by attaching a superparamagnetic bead to target molecules which are to be determined, magnetizing this bead with an applied magnetic field and using e.g. a Giant Magneto Resistance (GMR) sensor to detect the magnetic field of the magnetized beads.

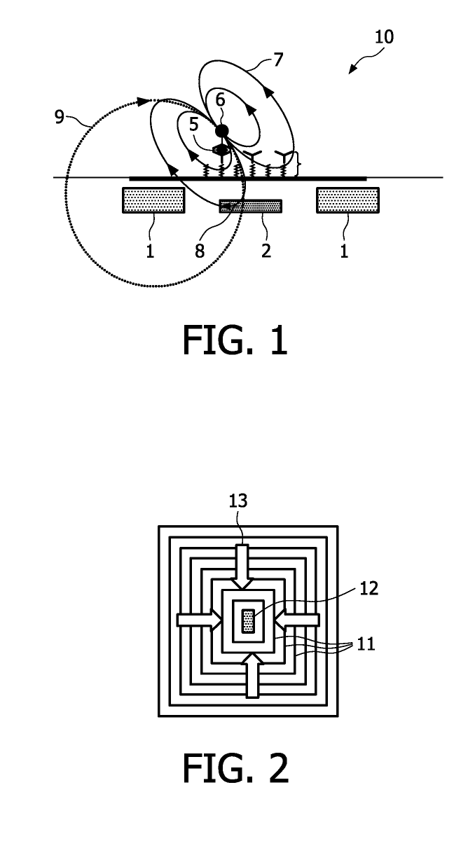

FIG. 1 illustrates a magnetoresistive sensor 10 with integrated magnetic field excitation. With integrated magnetic field excitation is meant that a magnetic field generating means is integrated in the magnetoresistive sensor 10. The magnetoresistive sensor 10 comprises two electric conductors 1 which form the magnetic field generating means and a GMR element 2 which forms a magnetoresistive sensor element. At the surface 3 of the magnetoresistive sensor 10, binding sites 4 are provided to which, for example, target molecules 5 with attached thereto a magnetic nanoparticle 6, can bind. A current flowing through the conductors 1 generates a magnetic field which magnetizes the magnetic nanoparticle 6. The magnetic nanoparticle 6 develops a magnetic moment m indicated by field lines 7 in FIG. 1. The magnetic moment m then generates dipolar magnetic fields, which have in-plane magnetic field components 8 at the location of the GMR element 2. Thus, the magnetic nanoparticle 6 deflects the magnetic field 9 induced by the current through the conductor 1, resulting in the magnetic field component 8 in the sensitive x-direction of the GMR element 2, also called x-component of the magnetic field Hₑₓₜ. The x-component of the magnetic field Hₑₓₜ is then sensed by the GMR element 2 and depends on the number Nₙₚ of magnetic nanoparticles 6 present at the surface 3 of the magnetoresistive sensor 10 and on the magnitude of the conductor current.

In order to speed up the biochemical assay, all target molecules and magnetic particles in the sample volume must approach the active sensor area in a relatively short time. Another requirement to such biosensors is that small fluid volumes of, for example, 1 microliter, can be actuated in a biosensor (e.g. for reagent mixing, stirring, homogenization), without disturbing a magnetic biosensor.

State-of-the-art solutions for these requirements are magnetic- and mechanical actuation (pumping), which both complicate the cartridge and the reader design. Furthermore, these solutions are difficult to apply to small sample volumes of, for example, 1 microliter.

Another known solutions for the above requirements is using external field generating means (e.g. coils) outside the sample volume. For stirring purposes, a rotor or a high density of magnetic particles may be provided in the fluid. However, large magnetic fields are required to generate a reasonable force on the magnetic beads in the sample volume and special measures have to be taken to not influence the GMR behaviour.

On-chip magnetic excitation, on the other hand, is only effective close to the surface where the magnetic field strength (gradient) is high. For example, a sensor may comprise neighbouring current wires. The wires attract magnetic particles or labels toward the sensor. However, in this way the sensor is exposed to still only a fraction of the particles in the total fluid volume above the sensor chip, because many particles hit the chip surface outside the reach of the field from the current wires. An additional disadvantage is that the external magnetic fields can easily disturb the GMR sensor.

It is an object of the present invention to provide an alternative or a good magnetic sensor, a biochip comprising at least one such magnetic sensor and an alternative or good method for detecting and/or quantifying target moieties in a sample fluid.

An advantage of the method and device according to embodiments of the present invention is that they can be applied to small sample volumes of e.g. 1 microliter.

Another advantage of the method and device according to embodiments of the present invention is that biochemical assays can be speeded up.

The above objective is accomplished by a method and device according to the present invention.

Particular and preferred aspects of the invention are set out in the accompanying independent and dependent claims. Features from the dependent claims may be combined with features of the independent claims and with features of other dependent claims as appropriate and not merely as explicitly set out in the claims.

In a first aspect of the present invention, a magnetic sensor device is provided for detecting and/or quantifying target moieties in a sample fluid. The magnetic sensor device comprises:
a first sensor chip having a top surface and binding sites,
means for attracting magnetic or magnetizable objects towards and onto the top surface of the sensor chip,
at least one sensor element for sensing the presence of magnetic or magnetizable objects, and
means for increasing a binding possibility of magnetic or magnetizable objects onto the binding sites by inducing a moving magnetic field.

According to embodiments of the invention, the at least one sensor element may be integrated in the first sensor chip.

Target moieties may include molecular species, cell fragments, viruses, etc.

According to the present invention, attracting magnetic or magnetizable objects towards and onto the surface may comprise attracting magnetic or magnetizable objects with attached thereto the target moieties which have to be detected. The target moiety/magnetic or magnetizable object combination then binds onto the binding sites on the sensor chip surface.

However, according to other embodiments of the invention, attracting magnetic or magnetizable objects towards and onto the surface may comprise attracting the magnetic or magnetizable objects and bind them onto immobilized target moieties or target-analogues on the sensor chip surface. In other words, the target molecules to be detected are first bound to the binding sites on the sensor chip surface and then the magnetic or magnetizable objects may be bound to the target moieties or target-analogues.

An advantage of the magnetic sensor device according to embodiments of the present invention is that the assay may be speeded up. A further advantage of the magnetic sensor device according to embodiments of the invention is that it may be used with small sample volumes of e.g. 1 μl without disturbing the operation of the magnetic sensor.

The means for attracting magnetic or magnetizable objects to the top surface of the sensor chip may, according to embodiments of the invention, be the same as the means for increasing the binding possibility of the magnetic or magnetizable objects onto the binding sites.

According to other embodiments of the invention, the means for attracting magnetic or magnetizable objects to the top surface of the sensor chip may comprise an integrated magnetic field generating means for generating a magnetic field for attracting the magnetic or magnetizable objects.

According to still other embodiments of the invention, the means for attracting magnetic or magnetizable objects to the top surface of the sensor chip may comprise means for exerting gravitational or centrifugal forces to the magnetic or magnetizable objects for attracting them to the sensor chip surface.

The means for increasing the binding possibility of magnetic or magnetizable objects onto the binding sites may, according to embodiments of the present invention, comprise a plurality of concentric current lines adapted for generating a moving magnetic field.

An advantage of these embodiments is that the magnetic or magnetizable objects, e.g. magnetic particles, are concentrated above the at least one sensor element which increases the probability of binding the magnetic or magnetizable objects to the binding sites present at the sensor chip surface and forming active area of the magnetic sensor.

According to other embodiments of the invention, the means for increasing a binding possibility of magnetic or magnetizable objects onto the binding sites may comprise a plurality of parallel current wires adapted for generating a moving magnetic field.

An advantage of these embodiments is that, by making a structure comprising a plurality of parallel current wires, magnetic or magnetizable objects may be moved over the sensor chip surface. This increases the binding possibility of the magnetic or magnetizable objects to the binding sites on the sensor chip surface because, when passing, for example, a first area comprising binding sites, there is a possibility that some magnetic or magnetizable objects do not bind to the binding sites on the sensor chip surface. Hence, by moving them, according to embodiments of the present invention, further along the sensor chip surface which comprises further areas with binding sites, the possibility of binding to other binding sites is increased.

The plurality of parallel current wires and the at least one sensor element may have a longitudinal direction, and the longitudinal direction of the current wires may be positioned substantially parallel to the longitudinal direction of the at least one sensor element.

Each of the plurality of parallel current wires and the at least one sensor element may have a longitudinal direction, wherein the longitudinal direction of the current wires may be positioned substantially perpendicular to the longitudinal direction of the at least one sensor element.

According to embodiments of the present invention, the plurality of parallel current wires may be positioned so as to form a closed circular configuration.

An advantage of this configuration is that the probability magnetic or magnetizable objects, e.g. magnetic particles, binding to active area of the magnetic sensor device may be enhanced.

According to other embodiments of the invention, the plurality of parallel current wires may form two closed circular configurations.

According to still other embodiments, the plurality of parallel current wires may be positioned in a linear configuration.

The magnetic sensor device may furthermore comprise at least one container for storing magnetic or magnetizable objects, e.g. magnetic particles.

An advantage of this configuration is that binding between target moieties and first-antibodies present on an active area of the magnetic sensor device may be facilitated, without the magnetic or magnetizable objects, e.g. magnetic particles, being able to interrupt this binding step.

The magnetic sensor device may furthermore comprise a fluid chamber having walls and the walls of the fluid chamber may be irregularly shaped. This increases the mixing effect in the sensor device. For example, the fluid chamber may comprise protrusions.

According to other embodiments, the fluid chamber may be optimised for low fluid friction. Optimising the fluid chamber for low fluid friction can, for example, be done by designing a hydro-dynamically smooth shape, i.e. the fluid chamber may be designed such that it has no protrusions at its inner surface, so that the fluid inside the fluid chamber is substantially not hindered in any way.

The magnetic sensor device may furthermore comprise a second sensor chip having a top surface and binding sites and comprising means for increasing a binding possibility of magnetic or magnetizable objects onto the binding sites by inducing a moving magnetic field, the second sensor chip being positioned with its top surface toward the top surface of the first sensor chip.

The present invention also provides a biochip comprising at least one magnetic sensor device according to embodiments of the present invention.

The present invention also provides the use of the magnetic sensor device according to embodiments of the present invention in molecular diagnostics, biological sample analysis or chemical sample analysis.

The present invention also provides the use of the biochip according to the present invention in molecular diagnostics, biological sample analysis or chemical sample analysis.

In a further aspect of the present invention, a method is provided for detecting and/or quantifying target moieties in a sample fluid. The method comprising:
providing the sample fluid to a magnetic sensor device,
attracting magnetic or magnetizable objects to a sensor chip surface of the magnetic sensor device, the sensor chip having binding sites, and
applying a moving magnetic field for increasing a binding possibility of magnetic or magnetizable objects onto the binding sites.

An advantage of the method according to embodiments of the present invention is that the assay may be speeded up. A further advantage of the method according to embodiments of the invention is that it is applicable to small sample volumes of e.g. 1 μl without disturbing the operation of the magnetic sensor.

According to embodiments of the invention, applying a moving magnetic field may be performed by sequentially actuating a plurality of concentric current lines.

An advantage of these embodiments is that the magnetic or magnetizable objects, e.g. magnetic particles, are concentrated above the at least one sensor element which increases the probability of binding to the binding sites present at the sensor chip surface and forming the active area of the magnetic sensor device.

According to other embodiments, applying a moving magnetic field may be performed by sequentially actuating a plurality of parallel current wires.

An advantage of these embodiments is that, by sequentially actuating a plurality of parallel current wires for applying a moving magnetic field, magnetic or magnetizable objects, e.g. magnetic particles, may be moved over the sensor chip surface. This increases the binding possibility of the magnetic or magnetizable objects, e.g. magnetic particles, to the binding sites on the sensor chip surface because, when passing, for example, a first area comprising binding sites, it may occur that some magnetic or magnetizable objects, e.g. magnetic particles, do not bind to the binding sites. Hence, by moving them further along the sensor chip surface which comprises further areas with binding sites, the possibility of binding to other binding sites is increased.

The method may furthermore comprise storing magnetic or magnetizable objects after having attracted them to the sensor chip surface.

Attracting magnetic or magnetizable objects, e.g. magnetic particles, to the sensor chip surface may be performed by applying a magnetic field.

Applying a magnetic field may be performed by flowing a current through a magnetic field generating means, preferably an integrated magnetic field generating means.

The magnetic field generating means may, for example, be a conductor such as e.g. a current wire.

The present invention also provides the use of the method according embodiments of the present invention in molecular diagnostics, biological sample analysis or chemical sample analysis.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

FIG. 1 illustrates the operation principle of a magnetoresistive sensor.

FIG. 2 schematically illustrates part of a magnetic sensor according to a first embodiment of the present invention.

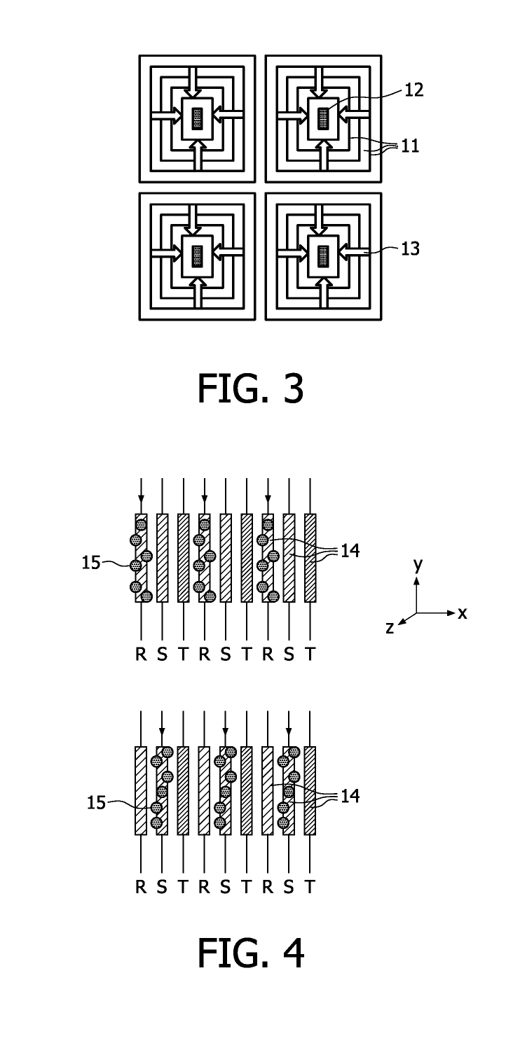

FIG. 3 schematically illustrates part of a magnetic sensor according to a first embodiment of the present invention.

FIG. 4 schematically illustrates part of a magnetic sensor according to a second embodiment of the present invention.

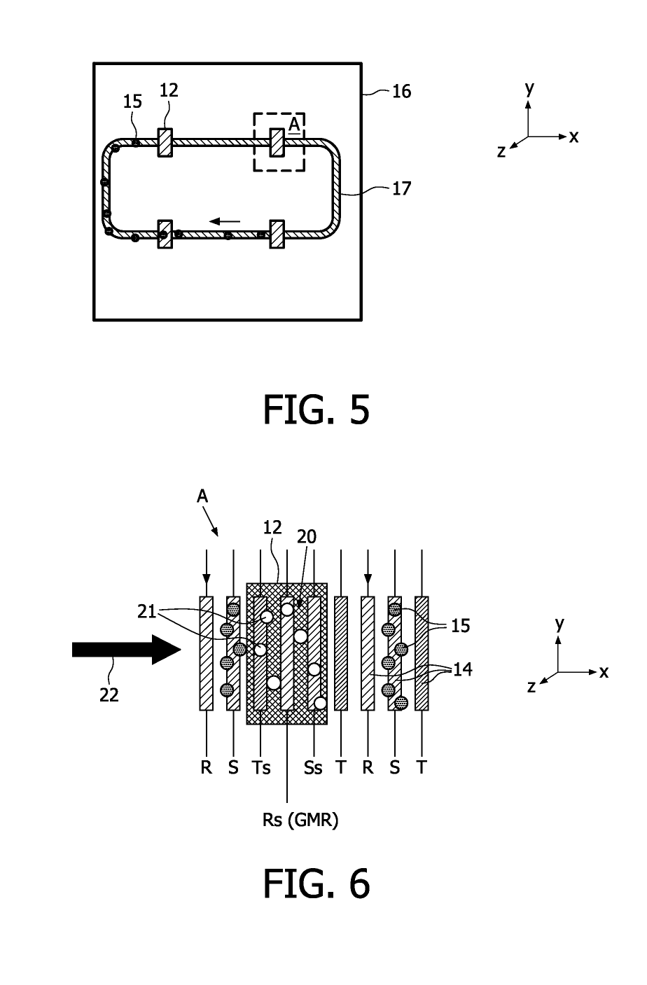

FIG. 5 schematically illustrates part of a sensor chip of a magnetic sensor according to embodiments of the present invention.

FIG. 6 schematically illustrates part of a magnetic sensor according to embodiments of the present invention.

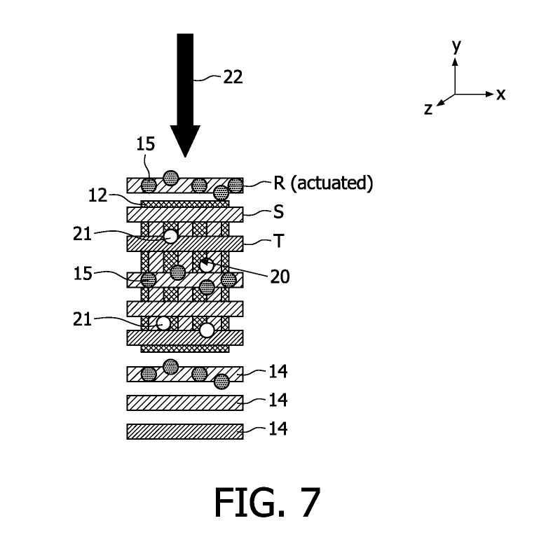

FIG. 7 schematically illustrates part of a magnetic sensor according to embodiments of the present invention.

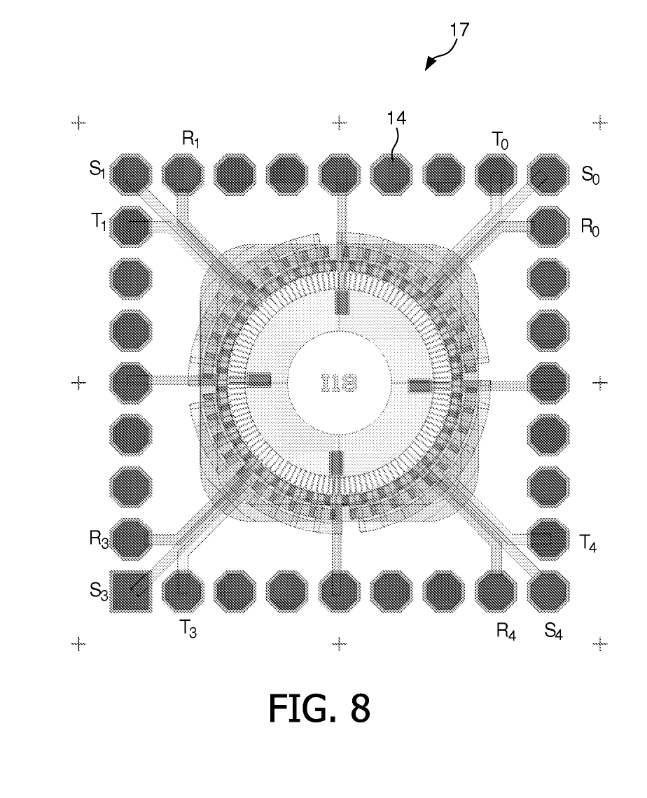

FIG. 8 shows a top view of the magnetic sensor as illustrated in FIG. 5.

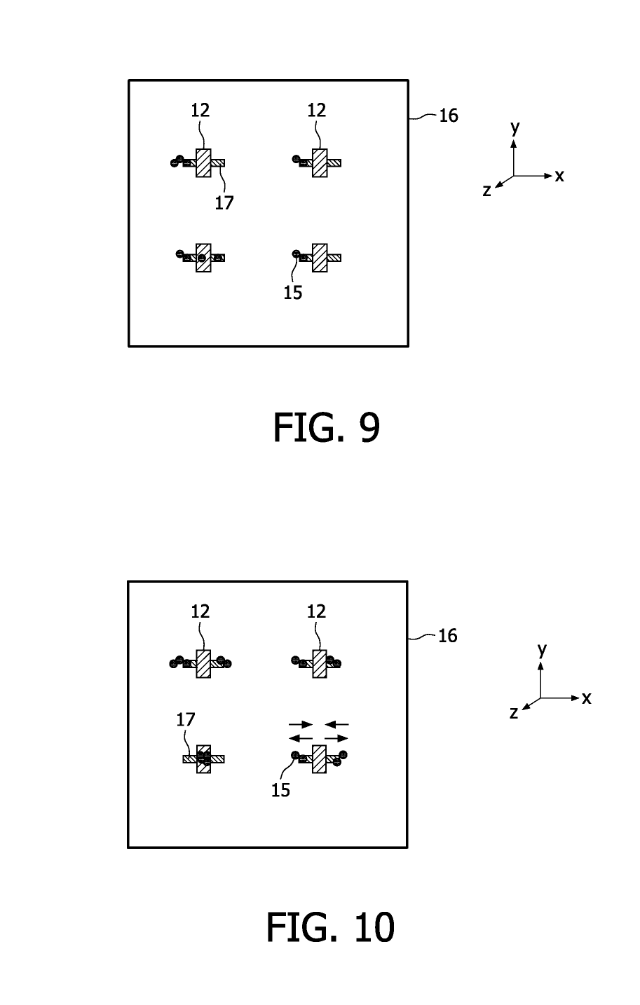

FIG. 9 schematically illustrates part of a magnetic sensor according to a third embodiment of the present invention.

FIG. 10 schematically illustrates part of a magnetic sensor according to a third embodiment of the present invention.

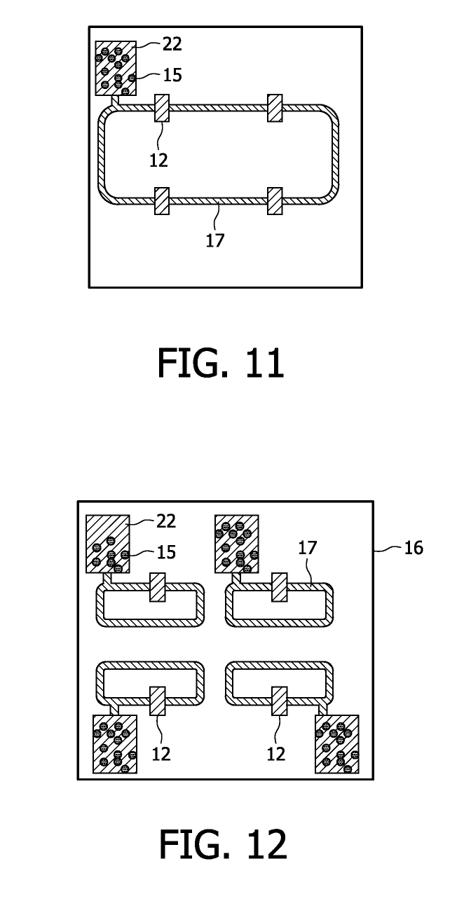

FIG. 11 schematically illustrates part of a magnetic sensor according to a fourth embodiment of the present invention.

FIG. 12 schematically illustrates part of a magnetic sensor according to a fourth embodiment of the present invention.

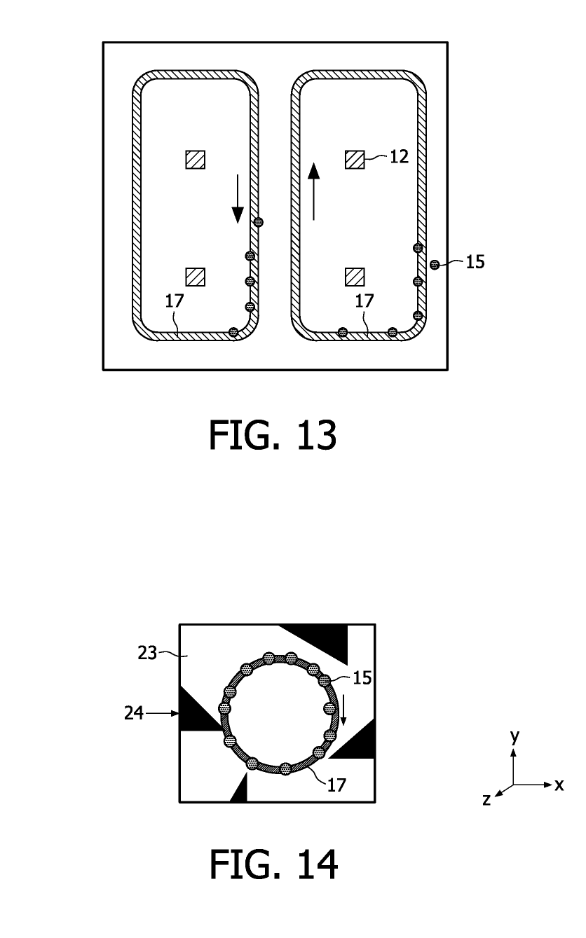

FIG. 13 schematically illustrates part of a magnetic sensor according to embodiments of the present invention.

FIG. 14 schematically illustrates part of a magnetic sensor according to embodiments of the present invention.

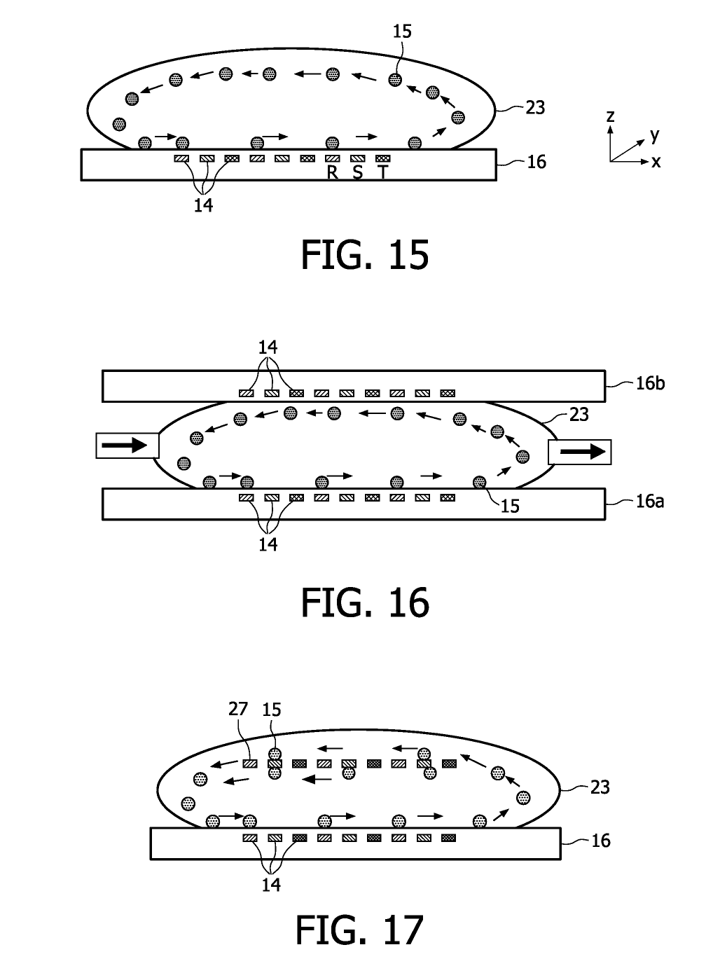

FIG. 15 schematically illustrates part of a magnetic sensor according to embodiments of the present invention.

FIG. 16 schematically illustrates part of a magnetic sensor according to embodiments of the present invention.

FIG. 17 schematically illustrates part of a magnetic sensor according to embodiments of the present invention.

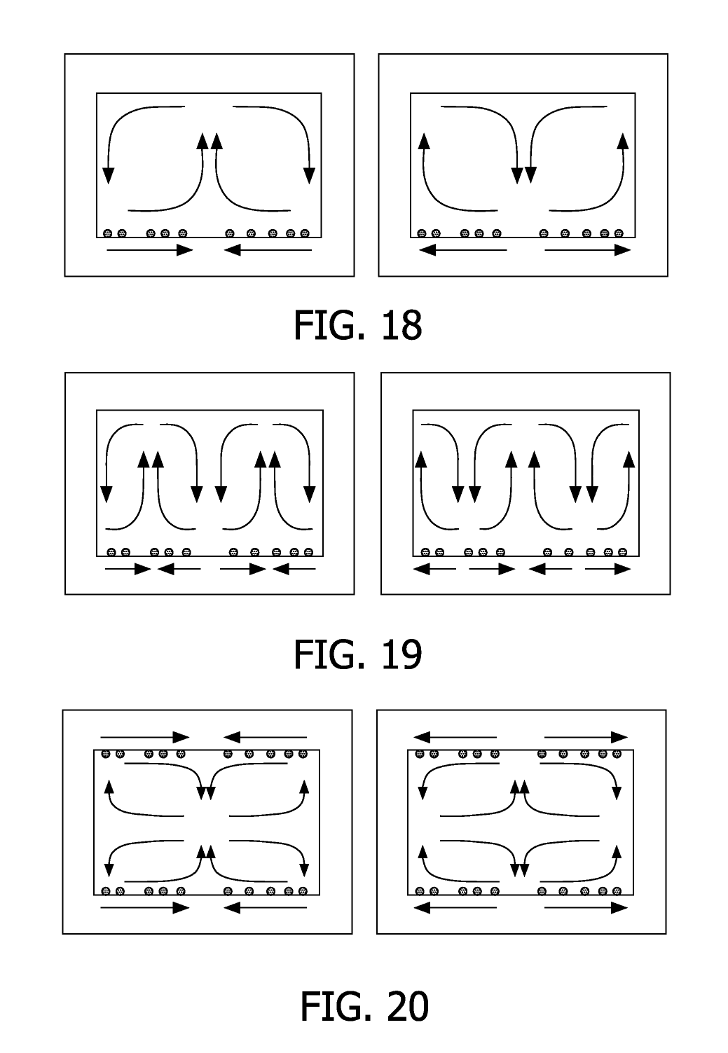

FIG. 18 to 21 schematically illustrate possible ways of moving magnetic or magnetizable objects over a sensor chip surface according to embodiments of the present invention.

FIG. 22 illustrates a biochip comprising magnetic sensors according to embodiments of the present invention.

In the different figures, the same reference signs refer to the same or analogous elements.

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

The present invention provides a magnetic sensor device for qualitative detecting and/or quantifying target moieties in a sample volume. Target moieties may include molecular species, cell fragments, viruses, etc. The sensor may be included on a biochip comprising at least one such a magnetic sensor device. Further, a method for qualitative detecting and/or quantifying target moieties in a sample volume using such a magnetic sensor device is provided. The magnetic sensor device, biochip and method according to the present invention may be used in any suitable application, e.g. molecular diagnostics, biological sample analysis or chemical sample analysis.

According to preferred embodiments of the invention, the magnetic sensor may be a biosensor for detecting and/or quantifying target moieties in a sample volume whereby, examples of target moieties that can be detected and/or quantified may be, but are not limited to:

Nucleic acids: DNA, RNA: either double or single stranded, or DNA-RNA hybrids or DNA-Protein complexes, with or without modifications.

Proteins or peptides, with or without modifications, e.g. antibodies, DNA or RNA binding proteins, enzymes, receptors, hormones, signalling proteins. Recently, grids with the complete proteome of yeast have been published.

Oligo- or polysaccharides or sugars.

Small molecules, such as inhibitors, ligands, cross-linked as such to a matrix or via a spacer molecule.

Hormones, drugs, metabolites

Cells or cell fractions or components such as external or internal membrane fragments, tissue fractions, etc.

In biosensing processes using a magnetic sensor device, magnetic particles or beads are directly or indirectly attached to target moieties. These target moieties are to be detected in a fluid, which can be the original sample or can already be processed before insertion into the biosensor (e.g. degraded, biochemically modified, filtered, or dissolved into a buffer). The fluids can be for example, biological fluids, such as saliva, sputum, blood, blood plasma, interstitial fluid or urine, or other fluids such as drinking fluids, environmental fluids, or a fluid that results from sample pre-treatment. The fluid can, for example, comprise elements of solid sample material, e.g. from biopsies, stool, food, feed, environmental samples.

One of the reasons why an assay can yield a high sensitivity is that the target moieties are concentrated from being dispersed rather thinly in a sample volume onto a sensor surface. A further enhancement in sensitivity can be obtained by enhancing lateral concentration of the target moieties on the surface. This is especially important to speed up, for example, a binding step that involves magnetic or magnetizable objects, e.g. magnetic nanoparticles, attached to the target moieties because this binding step is potentially slow because a magnetic or magnetizable object, e.g. magnetic nanoparticle, is relatively large and its binding is hindered by steric effects.

An aim of the present invention is to provide a magnetic sensor device and a method for detecting and/or quantifying target moieties in a sample volume which allow speeding up of the assay and in which small sample volumes of e.g. 1 microliter can be analysed without disturbing the operation of the magnetic sensor device.

Therefore, the generic idea of the present invention is to move magnetic or magnetizable objects, e.g. magnetic nanoparticles, across a chip surface in order to:
(1) collect or attract magnetic or magnetizable objects, e.g. magnetic nanoparticles, from a sample fluid bulk, and
(2) move the magnetic or magnetizable objects, e.g. magnetic nanoparticles, over active area of a magnetic sensor device.

By moving the magnetic or magnetizable objects, e.g. magnetic nanoparticles over the active area of the sensor, a fluid movement may be established inside the sample volume thereby inducing stirring of the fluid and the possibility of a magnetic or magnetizable object binding to binding sites on the sensor device may thereby be increased.

According to the present invention, the generic idea is realised by providing a magnetic sensor device comprising means for increasing a binding possibility of magnetic or magnetizable objects, e.g. magnetic nanoparticles, onto binding sites on a sensor chip surface by inducing a moving magnetic field. By inducing a moving magnetic field, magnetic or magnetizable objects may be moved over the sensor surface. By doing so, the possibility that these magnetic or magnetizable objects bind to binding sites on the sensor chip surface is increased (see further).

First, magnetic or magnetizable objects, e.g. magnetic nanoparticles, have to be attracted towards the surface of the magnetic sensor device.

According to the present invention, attracting magnetic or magnetizable objects, e.g. magnetic nanoparticles, towards and onto the surface may comprise attracting magnetic or magnetizable objects, e.g. magnetic particles, with attached thereto the target moieties which have to be detected. The target moiety/magnetic or magnetizable object combination then binds onto the binding sites on the sensor chip surface.

However, according to other embodiments of the invention, attracting magnetic or magnetizable objects, e.g. magnetic nanoparticles, towards and onto the surface may comprise attracting the magnetic or magnetizable objects, e.g. magnetic nanoparticles, and bind them onto immobilized target moiety or target-analogue on the sensor chip surface. In other words, the target moieties to be detected are first bound to the binding sites on the sensor chip surface and then the magnetic or magnetizable objects, e.g. magnetic nanoparticles, may be bound to the target moieties.

It has to be understood that when, in the further description and in the claims, is referred to attracting magnetic or magnetizable objects, e.g. magnetic nanoparticles, both the above described possibilities are disclosed.

Attracting may, according to embodiments of the invention, be done by a magnetic field generating means, e.g. by applying an electrical excitation current to a magnetic field generating means, such as e.g. conductor, which is part of the magnetic sensor device, or may be performed by moving a magnet into the appropriate position.

According to other embodiments of the invention, attracting the magnetic or magnetizable objects, e.g. magnetic nanoparticles, towards and onto the sensor chip surface may also be done by the means for increasing the binding possibility of magnetic or magnetizable objects, e.g. magnetic nanoparticles, onto binding sites on the sensor chip surface. The means for increasing a binding possibility of magnetic or magnetizable objects, e.g. magnetic nanoparticles, will attract the magnetic or magnetizable objects, e.g. magnetic nanoparticles, in all directions over the sensor surface. It has, however to be noted, that in this case the range in which magnetic or magnetizable objects, e.g. magnetic nanoparticles, will be attracted is limited so that only magnetic or magnetizable objects, e.g. magnetic nanoparticles, present close to the surface of the magnetic sensor will be attracted.

According to still other embodiments of the invention, getting the magnetic or magnetizable objects, e.g. magnetic nanoparticles, close to the surface does not necessarily require a magnetic force. This can also be achieved in a non-magnetic way, for example by gravitational or centrifugal forces.

A subsequent lateral collection process, induced by means for increasing a binding possibility of magnetic or magnetizable objects, e.g. magnetic nanoparticles, may, by moving the magnetic or magnetizable objects, e.g. magnetic nanoparticles, over the surface of the magnetic sensor device, bring these magnetic or magnetizable objects, e.g. magnetic nanoparticles, efficiently to the sensing surface or active area of the magnetic sensor, implemented by sensor elements.

The means for increasing a binding possibility of magnetic or magnetizable objects, e.g. magnetic nanoparticles to the sensor chip surface may be implemented by altering the magnetic state of static components in a sequence, for example, a plurality of current wires or current lines are actuated staggered in time, i.e. the one after the other, e.g. like a N-phase linear motor acting as a conveyor belt.

Alternatively, the means for increasing a binding possibility of magnetic or magnetizable objects, e.g. magnetic nanoparticles may also be implemented by, for example, a permanent magnet or an electromagnet which is positioned under (or above) the sensor chip of the magnetic sensor device and which is movable along the surface of the magnetic sensor device, hereby inducing a moving magnetic field. The movement may be performed by a suitable drive means.

The principle of the magnetic sensor device and the method according to embodiments of the present invention may be applicable to biosensor systems comprising at least one magnetic sensor device and a fluid chamber and using any suitable detection system, e.g. optical, electrochemical, impediametric and/or magnetic detection.

Moving or transporting magnetic or magnetizable objects, e.g. magnetic nanoparticles, over the sensor surface allows performing multiple functions:
Up-concentration of the magnetic or magnetizable objects, e.g. magnetic nanoparticles, to increase the binding speed and to assure that substantially every magnetic or magnetizable objects, e.g. magnetic nanoparticles, is involved in the binding process onto the sensor.
Transport of magnetic or magnetizable objects, e.g. magnetic nanoparticles, across the surface to assure that substantially all magnetic or magnetizable objects, e.g. magnetic nanoparticles, are exposed to each of the at least one sensor element which are part of the magnetic sensor device. This may be of interest when magnetic or magnetizable objects, e.g. magnetic nanoparticles, with different binding properties are used, where each type of magnetic or magnetizable objects, e.g. magnetic nanoparticles, can only bind to one particular sensor element, which could, for example, be the case when multiple analytes are to be measured at a same time.
Storing and subsequent transport of the magnetic or magnetizable objects, e.g. magnetic nanoparticles, towards the at least one sensor element to perform sequential magnetic labelling without the need for an additional liquid injection step.
Increased binding speed by repeatedly moving the magnetic or magnetizable objects, e.g. magnetic nanoparticles, across the sensor surface.

The magnetic sensor device according to the present invention comprises means for attracting magnetic or magnetizable objects, e.g. magnetic nanoparticles, to the sensor chip surface at least one sensor element, a fluidic chamber comprising the sample fluid with target moieties and means for increasing a binding possibility of magnetic or magnetizable objects, e.g. magnetic nanoparticles to the sensor chip surface by inducing a moving magnetic field.

According to an embodiment of the present invention, the means for attracting the magnetic or magnetizable objects, e.g. magnetic nanoparticles, to the surface of the sensor may be the same as the means for increasing a binding possibility of magnetic or magnetizable objects, e.g. magnetic nanoparticles.

However, according to preferred embodiments of the invention, the means for attracting the magnetic or magnetizable objects, e.g. magnetic nanoparticles, may comprise at least one magnetic field generating means, for example at least one conductor, for generating a magnetic field for attracting magnetic or magnetizable objects, e.g. magnetic nanoparticles, to the sensor surface.

The at least one magnetic field generating means may be provided on a same sensor chip as the at least one sensor element and the means for increasing a binding possibility of magnetic or magnetizable objects, e.g. magnetic particles, or may be located external to the chip. The chip may comprise the at least one sensor element and the plurality of current wires. In other words, the present invention may be applied to both on-chip as well as off-chip magnetic field generation.

Hereinafter, the invention will be described by means of different embodiments. It has to be understood that these embodiments are not limiting the invention in any way.

The present invention will be described by means of a magnetic sensor based on magnetoresistive sensor elements such as e.g. GMR elements. However, this is not limiting the invention in any way. The present invention may be applied to sensors comprising any sensor element suitable for detecting the presence or determining the amount of magnetic or magnetizable objects, e.g. magnetic nanoparticles, on or near a sensor surface based on any property of the particles. For example, detection of the magnetic or magnetizable objects, e.g. magnetic particles, may be done by means of magnetic methods (e.g. magnetoresistive sensor elements, Hall sensors, coils), optical methods (e.g. imaging fluorescence, chemiluminescence, absorption, scattering, surface plasmon resonance, Raman, . . . ), sonic detection (e.g. surface acoustic wave, bulk acoustic wave, cantilever, quartz crystal, etc.), electrical detection (e.g. conduction, impedance, amperometric, redox cycling), etc.

According to a first embodiment of the present the means for increasing a binding possibility of magnetic or magnetizable objects, e.g. magnetic nanoparticles, by inducing a moving magnetic field may be implemented by a plurality concentric current lines 11.

According to this first embodiment of the present invention, the concentric structures of current lines 11 can be used to concentrate magnetic or magnetizable objects, e.g. magnetic nanoparticles, near an active surface of the magnetic sensor device, the active area being implemented by at least one magnetoresistive element 12. Concentration of the magnetic or magnetizable objects, e.g. magnetic particles, may be done by actuating the current lines 11 in a three-phase fashion from the outside inwards, i.e. in the direction towards the at least one magnetoresistive element 12. FIG. 2 illustrates this for a magnetic sensor device comprising only one magnetoresistive element 12 and comprising a plurality, in the example given seven, concentric current lines 11. FIG. 3 illustrates part of a magnetic sensor device comprising four magnetoresistive elements 12, each magnetoresistive element 12 being encountered by a plurality of concentric current lines 11. It has to be understood that FIGS. 2 and 3 are only illustrative examples and do not limit the invention in any way. The magnetic sensor device may comprise any number of concentric current lines 11 and any number of magnetoresistive elements 12. Arrows 13 in FIGS. 2 and 3 indicate the direction in which the magnetic or magnetizable objects, e.g. magnetic nanoparticles, move towards the magnetoresistive element 12 according to this embodiment.

An advantage of this embodiment is that, after been attracted to the surface, the magnetic or magnetizable objects, e.g. magnetic particles, are concentrated above the at least one magnetoresistive element 12 which increases the probability of binding to binding sites present at the surface of the at least one magnetoresistive element 12 and forming active area of the magnetic sensor device.

According to a second embodiment of the present invention, the means for increasing a binding possibility of magnetic or magnetizable objects, e.g. magnetic nanoparticles, by inducing a moving magnetic field may be implemented by a plurality of parallel current wires 14, ordered as R, S and T wires. It has to be noted that, throughout the description, R, S and T used to indicate the current wires 14 do not have a particular meaning and that they are just used to ease indication of the sequence of the current wires. By sequentially actuating the current wires 14, magnetic or magnetizable objects, e.g. magnetic nanoparticles, may be attracted and transported across the surface of the sensor chip. This principle is illustrated in FIG. 4, which shows a top view of part of a chip surface of a magnetic sensor device.

By repetitive R-S-T wire actuation, the magnetic or magnetizable objects 15, e.g. magnetic nanoparticles, move to the right, i.e. in the x-direction as illustrated by the co-ordinate system in FIG. 4. The upper drawing in FIG. 4 illustrates the situation where the R wires are actuated and magnetic or magnetizable objects 15, e.g. magnetic nanoparticles, are concentrated at these R wires. When in a next step the S wires are actuated, as illustrated in the lower drawing of FIG. 4, magnetic or magnetizable objects 15, e.g. magnetic nanoparticles, are concentrated on the S-wires and are thus moved from the R- to the S-wires. This illustrates the movement of the magnetic or magnetizable objects 15, e.g. magnetic nanoparticles, to the right. However, when the actuation of the parallel current wires 14 is performed in a reversed sequence, i.e. T-S-R, the movement of the magnetic or magnetizable objects 15, e.g. magnetic nanoparticles, is reversed with respect to the S-T-R actuation and the magnetic or magnetizable objects 15, e.g. magnetic nanoparticles, move in the opposite direction, i.e. to the left. In this way, a linear bead-motor may be realized for moving magnetic or magnetizable 15 objects, e.g. magnetic nanoparticles, across the chip surface, e.g. over the at least one magnetoresistive element 12, or in general over the active area of magnetic sensor.

FIG. 5 shows a magnetic sensor device according to embodiments of the present invention, the magnetic sensor device comprising a chip area or chip sensor 16 on which four magnetoresistive elements 12 are located. The magnetic sensor device may furthermore comprise a plurality of parallel current wires 14 forming a closed configuration as can be seen from the figure. In the further description, this closed configuration will be referred to as bead motor 17. According to the example given in FIG. 5, the bead motor 17 may comprise a plurality of current wires 14 in repetitive R-S-T sequences, as illustrated before in FIG. 4. By sequentially actuating the current wires 14 in a predetermined sequence, i.e. R-S-T or T-S-T sequence, the magnetic or magnetizable objects 15, e.g. magnetic particles, may be moved in the x-direction respectively in the opposite direction of the x-direction. Magnetic or magnetizable objects 15, e.g. magnetic particles, passing over a magnetoresistive element 12, can bind to binding sites on the magnetoresistive element 12. Magnetic or magnetizable objects 15, e.g. magnetic particles, moving over a magnetoresistive element 12 without binding to it, are moved further along the bead motor 17 and can bind to a further magnetoresistive element 12. In that way, the probability of magnetic or magnetizable objects 15, e.g. magnetic particles, binding to active area of the magnetic sensor device is enhanced. According to the embodiment illustrated in FIG. 5 the closed configuration or bead motor 17 may be circular shaped bead motor 17.

By sequential actuation of the R-S-T wires 14, magnetic or magnetizable objects 15, e.g. magnetic nanoparticles, may move across the bead motor 17 and may in that way carry away the liquid in the sample volume, hence introducing a stirring activity in the sample fluid. This stirring effect in the sample fluid will speed up the assay. The design may be such that the magnetic or magnetizable objects 15, e.g. magnetic nanoparticles, are mainly attracted towards the, according to this embodiment, circular oriented current wires 14, because these wires have the highest current density.

Thus, according to the present embodiment, magnetic or magnetizable objects 15, e.g. magnetic nanoparticles may, driven by magnetic forces, for example coming from a magnetic field generated by a magnetic field generating means, be attracted towards the bead motor 17 and may be moved across the active area of each of the four magnetoresistive elements 12 as described above, thereby introducing a constant laminar fluid flow across the magnetoresistive elements 12, and thus inducing a stirring effect. As a result the probability of binding of the magnetic or magnetizable objects 15, e.g. magnetic nanoparticles, to target moieties is largely increased. The magnetic or magnetizable objects 15 may, according to other embodiments of the invention, also be attracted toward the sensor surface by the means for increasing a binding possibility of magnetic or magnetizable objects 15, e.g. magnetic nanoparticles, to the sensor chip surface or in a non-magnetic way, for example by gravitational or centrifugal forces. FIG. 6 shows detail A of the magnetic sensor as illustrated in FIG. 5. Detail A shows a plurality of parallel current wires 14 at the position of the magnetoresistive element 12. By sequentially actuating the R, S and T current wires 14, magnetic or magnetizable objects 15, e.g. magnetic nanoparticles, may be moved in the direction indicated by arrow 22, i.e. in the x-direction as indicated by the co-ordinate system in FIG. 6. When the magnetic or magnetizable objects 15, e.g. magnetic nanoparticles, come at the position of the magnetoresistive element 12, the target moieties they are bound to can then bind to binding sites on the active area 20 of the magnetic sensor device formed by the magnetoresistive element 12, and thus become immobilized magnetic or magnetizable objects 21. Magnetic or magnetizable objects 15, e.g. magnetic nanoparticles, that are not immobilized, are further moved along the bead motor 17 in the x-direction and can be bound to active area 20 of the other magnetoresistive elements 12.

In FIG. 7 an alternative configuration of the current wires 14 with respect to the magnetoresistive element 12 is illustrated, in which the parallel current wires 14 are extending in a direction substantially perpendicular to the direction in which the magnetoresistive element 12 extends. In other words, if the magnetoresistive element 12 extends in the Y-direction, the current wires 14 extend in the X-direction. This configuration avoids undesired magnetic fields in the magnetoresistive elements 12.

FIG. 8 furthermore shows a top view of the device as illustrated in FIG. 5, in which the circular shaped bead motor 17 comprising the plurality of current wires 14 which are circle-wise repeated. By circle-wise repeating the configuration as illustrated in FIG. 4, a circular bead-motor may be formed. In order to limit power consumption, each quadrant may independently be accessible via a separate R-S-T combination (see R₀S₀T₀, R₁S₁T₁, R₃S₃T₃, R₄S₄T₄) and a common ground connection.

According to a third embodiment of the present invention, the magnetic sensor device may comprise a short linear bead motor 17. This means, the bead motor 17 now has, contrary to the previous embodiment, no closed circular configuration, but has a linear configuration. Larger lengths of the linear bead motor 17 increase the ability to attract magnetic or magnetizable objects 15, e.g. magnetic nanoparticles, from the bulk towards the bead motor 17. Hence, more magnetic or magnetizable objects 15, e.g. magnetic nanoparticles, are transported towards the magnetic sensor device when the bead motor 17 comprises more current wires 14 and thus has a larger length. On the other hand, more power is needed to realise this benefit, i.e. more power is needed when the bead motor 17 comprises more current wires 14. Hence, a compromise has to be made by choosing a length, and thus an amount of current wires 14, for the bead motor 17 such that sufficient magnetic or magnetizable objects 15, e.g. magnetic nanoparticles, can be attracted to the sensor surface without the requirement for too much power. Hence, the length of the bead motor 17 depends on the application the bead motor 17 is used for.

This is illustrated in FIG. 9. Magnetic or magnetizable objects 15, e.g. magnetic nanoparticles, may be attracted from the bulk at a first side of the bead motor 17 which may be adapted for attracting the magnetic or magnetizable objects 15, e.g. magnetic nanoparticles. Subsequent, the magnetic or magnetizable objects 15, e.g. magnetic nanoparticles, may be transported over the active area 20 of the magnetoresistive elements 12 in the x-direction and/or in the y-direction. Magnetic or magnetizable objects 15, e.g. magnetic nanoparticles, may also be transported continuously towards and backwards from the sensitive or active area 20 of a magnetic sensor device from both sides of the magnetoresistive element 12, i.e. from a first side to a second side of the magnetoresistive element 12, the first and second side being opposite to each other. This is illustrated in FIG. 10.

According to a fourth embodiment according the present invention, a magnetic sensor device according to the second or third embodiment, may furthermore comprise a container 22. Magnetic or magnetizable objects 15, e.g. magnetic nanoparticles, may temporary be stored in the container 22 and may be transported towards the binding surfaces or active area of the magnetic sensor device when necessary. This may be done by sequentially actuating the current wires 14 forming a side part 23 of the bead motor 17 which connects the container 22 with the bead motor 17. Magnetic or magnetizable objects 15, e.g. magnetic particles, may then be moved over the surface of the magnetic sensor device as described above.

According to this third embodiment, prior to the binding process in an assay as known by persons skilled in the art, magnetic or magnetizable objects 15, e.g. magnetic nanoparticles, may be attracted towards the container 22, e.g. by means of a magnetic field generated in a magnetic field generating means. In the absence of magnetic or magnetizable objects 15, e.g. magnetic nanoparticles, binding between target moieties and first-antibodies present on the active area 20 of the magnetic sensor may be facilitated. At a certain point in time, the magnetic or magnetizable objects 15, e.g. magnetic nanoparticles, may be transported towards the at least one magnetoresistive element 12 or to the active area of the magnetic sensor device, where they may bind to the target moieties. This is called timed magnetic reagent release. Timed magnetic reagent release into the bulk of a fluidic chamber in order to implement an assay is first described in non published European patent application with application number EP 06111190.2.

Magnetic or magnetizable objects 15, e.g. magnetic nanoparticles, may then be guided over the sensitive area 20 of the magnetoresistive element 12, after which un-bonded magnetic or magnetizable objects 15, e.g. magnetic nanoparticles, can be stored back into the container 22. An example of such a magnetic sensor device is illustrated in FIG. 11, in which one container 22 is provided for all four magnetoresistive elements 12.

Alternatively, as illustrated in FIG. 12, a separate bead motor 17 and a separate container 22 may be provided for each magnetoresistive element 12. Each container 22 may comprise optimised magnetic or magnetizable objects 15, e.g. magnetic particles, for each of the magnetoresistive elements 12. This means that each of the containers 22 may, for example, comprise a different kind of magnetic or magnetizable objects 15, e.g. magnetic nanoparticles, which binds to different kind of target moieties. Hence, with this alternative configuration, different kinds of target moieties can be determined on a same magnetic sensor device at a same time.

According to embodiments of the invention, all the R-wires in the sequence of the plurality of current wires 14 may be actuated simultaneously as well as one after the other in order to avoid large instantaneous currents. The same principle applies for the S and T wires.

By sequentially actuating the plurality of current wires 14, in the magnetic sensor devices according to embodiments of the present invention, as already discussed a stirring effect may be obtained in at least part of the sample volume by the movement of the magnetic or magnetizable objects 15, e.g. magnetic nanoparticles.

According other embodiments of the invention, stirring of the sample volume may be implemented independent from the assay. This means that for the purpose of stirring the sample fluid in the fluidic chamber and for the purpose of detecting and/or quantifying target moieties in a sample fluid, different magnetic or magnetizable objects 15 may be used. For example, large magnetic or magnetizable objects 15 with a diameter in the range of e.g. 3 μm and without antibodies, which are easily attractable, may be used for the purpose of stirring. For the assay itself, i.e. for detecting and/or quantifying target moieties in a sample volume, smaller magnetic or magnetizable objects 15, e.g. magnetic nanoparticles, having a functionalised surface complementary to functional groups provided at the surface of the magnetoresistive elements 12 may be used.

Hereinafter, some embodiments will be described for increasing movement of liquid over the surface of the sensor, to induce a way of mixing the fluid sample comprising target moieties and magnetic or magnetizable objects 15, e.g. magnetic particles.

In order to increase mixing of the sample fluid, for example, the movement of the magnetic or magnetizable objects 15, e.g. magnetic nanoparticles, may repeatedly be reversed to enhance mixing of the sample fluid. Alternatively, mixing may be increased by providing other configurations of the bead motor 17 with respect to the magnetoresistive elements 12 on the chip area or sensor chip 16. FIG. 13 illustrates an example of such a configuration which may increase mixing of the fluid sample. It has to be understood that this is only an example and does not limit the invention. Other configurations of the bead motor 17 with respect to the magnetoresistive elements 12 are also disclosed in this invention. In the example of FIG. 13 the magnetic sensor device comprises two bead motors 17, each surrounding two magnetoresistive elements 12. By providing two bead motors 17 instead of one in the previous example, the degree of mixing may be enhanced.

In the magnetic sensor devices as described in the above embodiments, the generated fluid flow may occur parallel to the chip surface and may still not be optimal to stir the complete sample fluid. Therefore, according to embodiments of the present invention, alternative measures may additionally be taken in the fluid chamber to enhance mixing of the sample fluid.

Hereinafter, different embodiments will be described for increasing the mixing of the sample fluid in the fluid chamber. The following embodiments can each be applied to each of the magnetic sensor devices as described in the above embodiments.

According to one embodiment of the present invention, the fluid chamber 23 of the magnetic sensor device may be provided with irregular shaped walls 24. With irregular shaped walls 24 is meant that the walls are not straight, but show some irregularities in their shape. For example, baffles or rod protrusions can be used to create complex flow patterns that further enhance the mixing. Typically, the fluid chamber 23 may be such that the protrusions are an integral part of the fluid chamber 23. Because, when inducing a stirring effect in the sample fluid by the means for increasing a binding possibility of magnetic or magnetizable objects 15, e.g. magnetic nanoparticles, to the sensor chip surface of the magnetic sensor device by means of a moving magnetic field, the irregularities of the walls 24 further increase the stirring effect as they interrupt the movement of the sample fluid and thereby oblige the sample fluid to take another route in the fluid chamber 23.

According to another embodiment of the present invention, the fluid chamber 23 may be optimised for low fluid friction. As a result, the fluid flow may be more generated or directed in the vertical direction, i.e. in the z-direction (see FIG. 15). Optimising the fluid chamber 23 for low fluid friction can, for example, be done by designing a hydrodynamically smooth shape, i.e. the fluid chamber 23 may be designed such that it has no protrusions at its inner surface, so that the fluid inside the fluid chamber 23 is substantially not hindered in any way.

According to still a further embodiment of the present invention, the magnetic sensor device may comprise a first sensor chip 16a and a second sensor chip 16b, each having a top surface 25a resp. 25b, which are located with their top surfaces 25a,25b toward each other, hence forming a sandwich geometry with a fluid chamber 23 in between the two sensor chips 16a,16b, as is illustrated in FIG. 16. Both sensor chips 16a,16b may drive the magnetic or magnetizable objects 15, e.g. magnetic nanoparticles, whereas at least one of the first and second sensor chip 16a, 16b comprises a magnetoresistive element 12. By actuating the current wires 14 in one sensor chip (e.g. 16a) at a time, the magnetic or magnetizable objects 15, e.g. magnetic nanoparticles, may be attracted from the opposite sensor chip 16b towards the sensor chip 16a which comprises the actuated current wires 14. This may also be an alternative implementation of magnetic washing, i.e. removing magnetic or magnetizable objects 15, e.g. magnetic nanoparticles, which are not bound to the surface of the magnetic sensor device.

In a further embodiment of the invention, the magnetic sensor device may comprise a sensor chip 16 as described in embodiments of the invention. In the example given in this embodiment and illustrated in FIG. 17, the sensor chip 16 may comprise a plurality of current wires 14. Above the sensor chip 16, the magnetic sensor device may comprise any suitable electrical connections, e.g. on chip bonding wires 27. Preferably, the plurality of wires 14 may preferably be positioned in the sensitive direction of the magnetoresistive elements 12 to avoid undesired magnetic fields in these elements. The on chip bonding wires 27 may be used for attracting magnetic or magnetizable objects 15, e.g. magnetic elements, away from the sensor chip 16. Again, this is a possible alternative for washing, i.e. removing magnetic or magnetizable objects 15, e.g. magnetic nanoparticles, which are not bound to the surface of the magnetic sensor device.

According to a further embodiment of the invention, not only mixing due to the movement of liquid over the surface of the magnetic sensor device may be induced, but also a mixing process in the bulk may be involved by inducing vertical vortices. By moving the liquid over the surface of the sensor chip 16 as described in embodiments according to the invention, in opposite directions, the liquid may be forced to move in a vertical direction, thereby inducing bulk mixing. By alternating the direction of the movement, i.e. by changing the sequence in which the plurality of current wires 14 are actuated, the direction of the vortex can be changed. This also helps to prevent that the magnetic or magnetizable objects 15, e.g. magnetic particles, are collected in one location. This is illustrated in FIG. 18.

Increasing the number of times the movement of the magnetic or magnetizable objects 15, e.g. magnetic particles, changes direction can be used to increase the number of vortices in the horizontal plane (see FIG. 19).

By adding magnetic or magnetizable object-induced pumping, for example, by using a substrate with integrated conductors, on top of the fluid chamber 23 it is possible to increase the number of vortices in the vertical plane, in that way further enhancing the mixing.

By alternating the different pumping schemes in time very complex mixing patterns can be generated as is illustrated in FIG. 20.

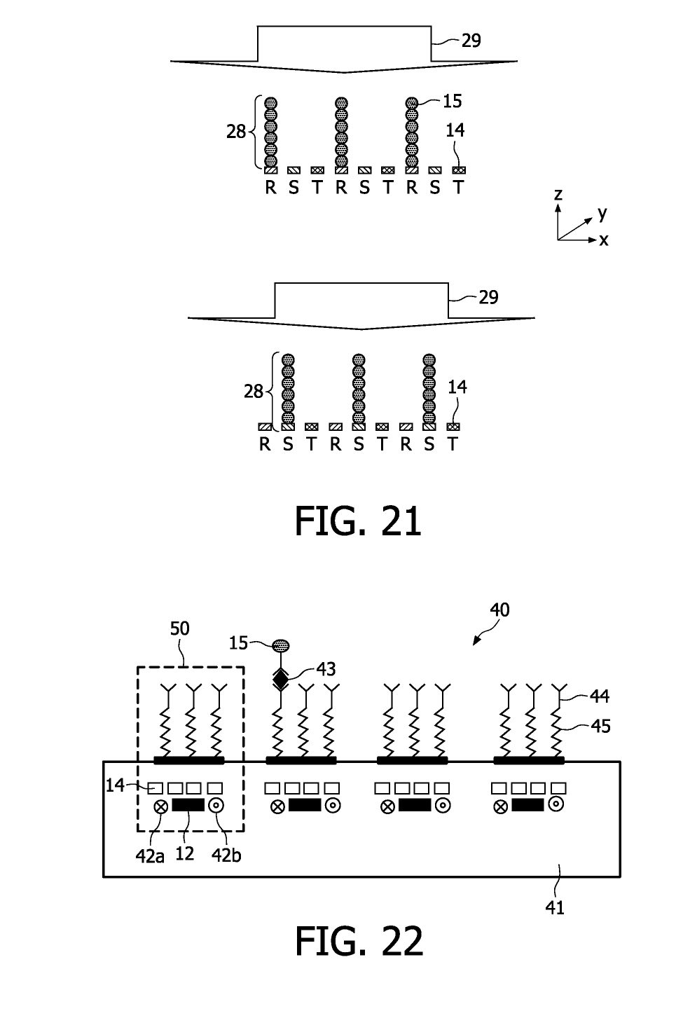

According to yet other embodiments of the invention, a stirring effect may be obtained by moving magnetic chains 28 formed by magnetic or magnetizable objects 15, e.g. magnetic particles, across the surface of the sensor chip 16. By applying a vertical magnetic field, indicated by reference number 29, vertical oriented magnetic chains 28 may be formed which, comparable to hairs of a brush and may carry away the fluid more effectively. This is illustrated in FIG. 21. The upper part of the drawing illustrates the situation where the R wires are actuated, while the lower part of the drawing illustrates the situation where the S wires are actuated, in that way illustrating the movement of the magnetic chains 28 over the surface of the sensor chip 16 in the x-direction. By changing the sequence of the actuation of the wires form R-S-T to T-S-R, the direction in which the magnetic chains 28 move may be changed to the left, i.e. to the opposite direction of the x-direction.

An advantage of the device and method according to embodiments of the present invention is that the magnetic sensor can have a lower detection limit than prior art devices and may provide faster binding.

Another advantage of the method and device according to embodiments of the present invention is that they can be applied to small sample volumes of e.g. 1 microliter without disturbing the operation of the magnetic sensor device.

Furthermore, the device and method according to the present invention allow on-chip manipulation of magnetic or magnetizable objects 15, e.g. magnetic particles, for easy cartridge and reader implementation.

Moreover, an efficient transport of magnetic or magnetizable objects 15, e.g. magnetic particles, over the active area of the magnetic sensor device may be provided.

The method and device according to the present invention is compatible with magnetically timed reagent release.

A further advantage of the present invention is that it provides a magnetic sensor device and a method for detecting and/or quantifying target moieties in a sample fluid which is rapid, easy and cheap.

Furthermore, the device and method according to embodiments of the present invention is widely applicable to all biosensors having a fluid chamber.

In another aspect, the present invention also provides a biochip 40 comprising at least one magnetic sensor device 50 according to embodiments of the present invention as described above. FIG. 22 illustrates a biochip 40 according to an embodiment of the present invention. The biochip 40 may comprise at least one magnetic sensor device 50 according to embodiments of the present invention which is integrated in a substrate 41. The term “substrate” may include any underlying material or materials that may be used, or upon which a device, a circuit or an epitaxial layer may be formed. The term “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include, for example, an insulating layer such as a SiO₂ or an Si₃N₄ layer in addition to a semiconductor substrate portion. Thus the term “substrate” also includes glass, plastic, ceramic, silicon-on-glass, silicon-on-sapphire substrates. The term “substrate” is thus used to define generally the elements for layers that underlie a layer or portions of interest. Also the “substrate” may be any other base on which a layer is formed, for example a glass or metal layer.

According to embodiments of the invention a single magnetic sensor device 50 or a multiple of magnetic sensor devices 50 may be integrated on the same substrate 41 to form the biochip 40.

The magnetic field generator 42a, 42b of the magnetic sensor devices 50 may be magnetic field generators external to the substrate 41, or, as in the present example illustrated in FIG. 22, may also be integrated in the substrate 41. According to the present example, the magnetic field generator may comprise a first and a second electrical conductor, e.g. implemented by a first and second current conducting wire 42a and 42b. Also other means instead of current conducting wires 42a, 42b may be applied to generate the external magnetic field. Furthermore, the magnetic field generator may also comprise another number of electrical conductors. According to other embodiments, the magnetic field generator may also be located outside the substrate 41. The magnetic sensor devices 50 also comprises a plurality of wires 14 adapted for alternately being actuated as discussed in the embodiments of the present invention.

In each magnetic sensor device 50 at least one magnetoresistive element 12, for example a GMR element, may be integrated in the substrate 41 to read out the information gathered by the biochip 40, thus for example to read out the presence or absence of target particles 43 via magnetic or magnetizable objects 15, e.g. magnetic nanoparticles, attached to the target particles 43, thereby determining or estimating an areal density of the target particles 43. The magnetic or magnetizable objects 15, e.g. magnetic particles, are preferably implemented by so called superparamagnetic beads. Binding sites 44 which are able to selectively bind a target moiety 43 are attached on a probe element 45. The probe element 45 is attached on top of the substrate 41.

The functioning of the biochip 40, and thus also of the magnetic sensor device 50, will be explained hereinafter. Each probe element 45 may be provided with binding sites 44 of a certain type, for binding pre-determined target moieties 43. A target sample, comprising target moieties 43 to be detected, may be presented to or passed over the probe elements 45 of the biochip 40, and if the binding sites 44 and the target moieties 43 match, they bind to each other. The superparamagnetic beads 15, or more generally the magnetic or magnetizable objects, may be directly or indirectly coupled to the target moieties 43. The magnetic or magnetizable objects, e.g. superparamagnetic beads 15, allow to read out the information gathered by the biochip 40.

In the embodiment illustrated in FIG. 22, the external magnetic field magnetizes the magnetic or magnetizable objects, e.g. the superparamagnetic beads 15, which as a response generate a magnetic field which can be detected by the magnetoresistive element 12, e.g. GMR element. Although not necessary, the magnetoresistive element 12, e.g. GMR element, should preferably be positioned in such a way that the parts of the response magnetic field generated by the magnetic or magnetizable objects 15 which pass through the magnetoresistive element 12, e.g. GMR element, lie in the sensitive direction of the magnetoresistive element 12, e.g. GMR element. Movement of the magnetic or magnetizable objects 15 over the surface of the chip 40 may be achieved as described above in embodiments of the invention.

In addition to molecular assays, also larger moieties can be detected, e.g. cells, viruses, or fractions of cells or viruses. Detection can occur with or without scanning of the sensor element with respect to the biosensor surface. The magnetic or magnetizable objects 15, e.g. magnetic particles, can be detected directly by the sensing method, or the magnetic or magnetizable objects, e.g. magnetic particles, can be further processed prior to detection. An example of this further processing is that materials may be added or that the (bio)chemical or physical properties of the magnetic or magnetizable objects 15, e.g. magnetic particles, may be modified to facilitate detection.

The magnetic sensor device, biochip 40 and method according to the present invention can be used with several biochemical assay types, such as e.g. binding/unbinding assay, sandwich assay, competition assay, displacement assay, enzymatic assay, etc.

The magnetic sensor device, biochip and method according to this invention are suitable for being used in sensor multiplexing (i.e. the parallel use of different sensors and sensor surfaces), label multiplexing (i.e. the parallel use of different types of labels) and chamber multiplexing (i.e. the parallel use of different reaction chambers).

The magnetic sensor device, biochip and method according to the present invention can be used as rapid, robust, and easy to use point-of-care biosensors for small sample volumes. The fluid chamber 23 can, for example, be a disposable item to be used with a compact reader, containing the one or more magnetic field generating means and one or more detection means.

Furthermore, the magnetic sensor device, biochip and method according to the present invention can be used in automated high-throughput testing. In this case, the fluid chamber 23 may be e.g. a well plate or cuvette, fitting into an automated instrument.

It is to be understood that although preferred embodiments, specific constructions and configurations, as well as materials, have been discussed herein for devices according to the present invention, various changes or modifications in form and detail may be made without departing from the scope and spirit of this invention. For example, according to other embodiments of the present invention, the means for increasing a binding possibility of magnetic or magnetizable objects 15, e.g. magnetic particles, onto the binding sites on the sensor chip surface by inducing a moving magnetic field. may also be implemented by, for example, a magnetic which is positioned under (or above) the substrate of the magnetic sensor device and which is movable along the surface of the magnetic sensor device, hereby inducing a moving magnetic field.

1. A magnetic sensor device for detecting and/or quantifying target moieties in a sample fluid, the magnetic sensor device comprising:
a first sensor chip (16, 16a) having a top surface and binding sites,
means for attracting magnetic or magnetizable objects (15) towards and onto the top surface of the sensor chip (16, 16a),
at least one sensor element (12) for sensing the presence of magnetic or magnetizable objects (15), and
means (11, 14) for increasing a binding possibility of the magnetic or magnetizable objects (15) onto the binding sites by inducing a moving magnetic field.

2. Magnetic sensor device according to claim 1, wherein the at least one sensor element (12) is integrated in the first sensor chip (16, 16a).

3. Magnetic sensor device according to claim 1 wherein the means for increasing a binding possibility of magnetic or magnetizable objects (15) onto the binding sites comprises a plurality of concentric current lines (11) adapted for generating a moving magnetic field.

4. Magnetic sensor device according to claim 1, wherein the means for increasing a binding possibility of magnetic or magnetizable objects (15) onto the binding sites comprises a plurality of parallel current wires (14) adapted for generating a moving magnetic field.

5. Magnetic sensor device according to claim 4, wherein the plurality of parallel current wires (17) are positioned so as to form a closed circular configuration.

6. Magnetic sensor device according to claim 1, furthermore comprising at least one container (22) for storing magnetic or magnetizable objects (15).

7. A biochip (40) comprising at least one magnetic sensor device according to claim 1.

8. A method for detecting and/or quantifying target moieties in a sample fluid, the method comprising:
providing the sample fluid to a magnetic sensor device,
attracting magnetic or magnetizable objects (15) to a sensor chip surface of the magnetic sensor device, the sensor chip surface having binding sites, and
applying a moving magnetic field for increasing a binding possibility of magnetic or magnetizable objects (15) onto the binding sites.

9. A method according to claim 8, wherein applying a moving magnetic field may be performed by sequentially actuating a plurality of concentric current lines (11).

10. A method according to claim 8, wherein applying a moving magnetic field may be performed by sequentially actuating a plurality of parallel current wires (14).
